(19) United States
(12) Patent Application Publication
(10) Pub. No.: US 2024/0407223 A1
(43) Pub. Date: Dec. 5, 2024

(54) DISPLAY DEVICE

(71) Applicant: Sharp Display Technology Corporation, Kameyama City, Mie (JP)

(72) Inventors: Jun SAKUMA, Kameyama City, Mie (JP); Yasushi ASAOKA, Kameyama City, Mie (JP)

(21) Appl. No.: 18/698,346

(22) PCT Filed: Dec. 7, 2021
(86) PCT No.: PCT/JP2021/044900

§ 371 Date: Apr. 3, 2024

(51) Int. Cl. H10K 59/38; H10K 50/115

(52) U.S. Cl. CPC H10K 59/38; H10K 50/115

(57) ABSTRACT

Sb1<Eb×Sb2 is satisfied, where Eb is the energy conversion efficiency of a blue-wavelength conversion layer, where Sb1 is the standard photopic luminous efficiency of first blue light, where Sb2 is the standard photopic luminous efficiency of second blue light.

### TECHNICAL FIELD

The present disclosure relates to a display device.

### BACKGROUND ART

Display devices have been required to emit high-luminance blue light.

### CITATION LIST

### Patent Literatures

Patent Literature 1: Japanese Unexamined Patent Application Publication No. 2016-001564
Patent Literature 2: Japanese Unexamined Patent Application Publication No. 2021-089425
Patent Literature 3: Japanese Unexamined Patent Application Publication No. 2019-083203

### SUMMARY

### Technical Field

Blue light is classified into the following: first blue light whose peak wavelength is 455 nm or less; and second blue light whose peak wavelength is longer than that of the first blue light and is 490 nm or less.

It is difficult for a user to achieve the first blue light of high luminance because the standard photopic luminous efficiency of the first blue light is low. Further, the first blue light falls under so-called blue light. In view of the foregoing, it is not preferable to positively use the first blue light as blue light that is emitted by a display device.

On the other hand, developments of electroluminescence materials that are suitable for achieving the second blue light of high luminance, and that emit blue light that has high efficiency, and whose peak wavelength is longer than 455 nm have been unsatisfactory.

In view of the foregoing, it is unfortunately difficult for display devices according to known techniques to emit high-luminance blue light.

### Solution to Problem

A display device according to one aspect of the present disclosure includes the following: a blue light-emitting layer composed of an organic light-emitting diode or a quantum-dot light-emitting diode; and a blue-wavelength conversion layer, wherein the blue light-emitting layer is configured to emit first blue light having a peak wavelength of 455 nm or less, the blue-wavelength conversion layer is provided over at least the blue light-emitting layer and is configured to convert the first blue light into second blue light having a peak wavelength that is longer than the peak wavelength of the first blue light and is 490 nm or less, and Sb1<Eb×Sb2 is satisfied, where Eb is the energy conversion efficiency of the blue-wavelength conversion layer, where Sb1 is the standard photopic luminous efficiency of the first blue light, where Sb2 is the standard photopic luminous efficiency of the second blue light.

### Advantageous Effect of Disclosure

The aspect of the present disclosure facilitates emission of high-luminance blue light.

### BRIEF DESCRIPTION OF DRAWINGS

FIG. 1 is a sectional view of a schematic configuration of a display device according to a first embodiment of the present disclosure.

FIG. 2 is a sectional view of a schematic configuration of a display device according to a second embodiment of the present disclosure.

FIG. 3 is a sectional view of a schematic configuration of a display device according to a third embodiment of the present disclosure.

FIG. 4 is a sectional view of a schematic configuration of a display device according to a fourth embodiment of the present disclosure.

### DESCRIPTION OF EMBODIMENTS

Embodiments of the present disclosure will be described below. It is noted that for convenience in description, components having the same functions as those of earlier described components will be denoted by the same signs, and that their description will not be repeated in some cases.

### First Embodiment

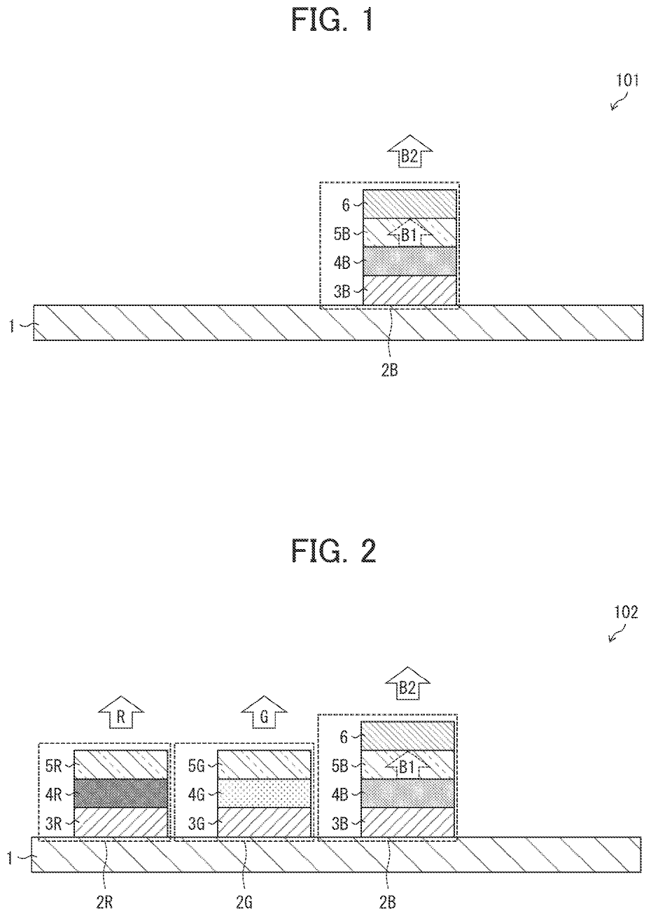

FIG. 1 is a sectional view of a schematic configuration of a display device 101 according to a first embodiment of the present disclosure. The display device 101 includes a substrate 1 and a blue light-emitting portion 2B. The blue light-emitting portion 2B is provided on the substrate 1.

The blue light-emitting portion 2B has a reflective electrode 3B, a blue light-emitting layer 4B that emits first blue light B1, and a transparent electrode 5B. The reflective electrode 3B, the blue light-emitting layer 4B, and the transparent electrode 5B are stacked in the stated order on the substrate 1. The blue light-emitting layer 4B emits the first blue light B1 in response to a current that flows between the reflective electrode 3B and transparent electrode 5B and is composed of an organic light-emitting diode (OLED) or a quantum-dot light-emitting diode (QLED). Blue light is defined as light whose peak wavelength ranges from 400 nm inclusive to 490 nm exclusive. The first blue light B1 is defined as light that is the aforementioned blue light or is ultraviolet light, and whose peak wavelength is 455 nm or less. The first blue light B1 is light whose peak wavelength ranges from, for instance, 400 to 455 nm inclusive.

The reflective electrode 3B is a light-reflective electrode. The transparent electrode 5B is a light-transparent electrode. The reflective electrode 3B may be replaced with a light-transparent electrode, and at this time, the substrate 1 may be light-transparent as well.

A carrier functional layer may be formed as necessary between the reflective electrode 3B and blue light-emitting layer 4B, and between the blue light-emitting layer 4B and transparent electrode 5B. Examples of the carrier functional layer include a hole injection layer, a hole transport layer, an electron injection layer, and an electron transport layer.

The blue light-emitting portion 2B further has a blue-wavelength conversion layer 6. The blue-wavelength conversion layer 6 is provided over at least the blue light-emitting layer 4B and is stacked on the transparent electrode 5B in FIG. 1. The blue-wavelength conversion layer 6 converts the first blue light B1 into second blue light B2, and this layer mainly subjects the first blue light B1 emitted by the blue light-emitting layer 4B to wavelength conversion and emits the second blue light B2 obtained through the wavelength conversion. The second blue light B2 is defined as light that is the foregoing blue light, and whose peak wavelength is longer than that of the first blue light B1 and is 490 nm or less.

The energy conversion efficiency of the blue-wavelength conversion layer 6 will be denoted by Eb. Eb is defined by the ratio of whole light energy that is radiated from a certain substance to light energy that is absorbed by the certain substance, at the time when the certain substance is caused to absorb monochromatic light having a peak that is the peak wavelength of the first blue light B1.

The standard photopic luminous efficiency of the first blue light B1 will be denoted by Sb1. Sb1 is defined by the standard photopic luminous efficiency at the peak wavelength of the first blue light B1.

The standard photopic luminous efficiency of the second blue light B2 will be denoted by Sb2. Sb2 is defined by the standard photopic luminous efficiency at the peak wavelength of the second blue light B2.

With regard to Eb, Sb1, and Sb2 above, Sb1<Eb×Sb2 is satisfied.

The display device 101 can emit the second blue light B2 without using an electroluminescence material that emits blue light that has high efficiency, and whose peak wavelength is longer than 455 nm. Accordingly, the display device 101 can easily emit high-luminance blue light.

The blue-wavelength conversion layer 6 is preferably cadmium-free. This can achieve the blue-wavelength conversion layer 6 with low toxicity. It is noted that the blue-wavelength conversion layer 6 being cadmium-free is defined as that the mass ratio of cadmium (Cd) contained in the blue-wavelength conversion layer 6 stands at less than 1% when the mass ratio of the wavelength conversion material contained in the blue-wavelength conversion layer 6 stands at 100%.

The blue-wavelength conversion layer 6 contains a first quantum dot material, and the first quantum dot material preferably has a core made of any of indium phosphide (InP), ZnSe, ZnSeTe, and ZnTe. Thus, the display device 101 can easily emit the second blue light B2 of high luminance.

The blue light-emitting layer 4B is preferably cadmium-free. This can achieve the blue light-emitting layer 4B with low toxicity. It is noted that the blue light-emitting layer 4B being cadmium-free is defined as that the mass ratio of Cd contained in the blue light-emitting layer 4B stands at less than 1% when the mass ratio of the light-emitting material contained in the blue light-emitting layer 4B stands at 100%.

The blue light-emitting layer 4B contains a second quantum dot material, and the second quantum dot material preferably has a core made of any of ZnSe, ZnSeTe, and ZnTe. Accordingly, the display device 101 can easily emit the first blue light B1 of high luminance, and by extension, the second blue light B2 of high luminance.

Light that is obtained from each of the first quantum dot material and second quantum dot material has high monochromaticity. In other words, the blue-wavelength conversion layer 6, which contains the first quantum dot material, and/or the blue light-emitting layer 4B, which contains the second quantum dot material, can offer the second blue light B2 of a desirable color without passing the second blue light B2 through a color filter. This leads to easy emission of the second blue light B2 of high luminance.

The peak wavelength of the second blue light B2 is longer than 455 nm; in the spectrum of light that is emitted by the blue light-emitting portion 2B having the blue light-emitting layer 4B and blue-wavelength conversion layer 6, the spectral radiance of light at a peak that is longer than wavelength 455 nm resulting from the second blue light B2 may be larger than the spectral radiance of light at a peak that is equal to or less than wavelength 455 nm resulting from the first blue light B1. In addition, the spectrum of light that is emitted by the blue light-emitting portion 2B having the blue light-emitting layer 4B and blue-wavelength conversion layer 6 does not have to include a peak that is equal to or less than wavelength 455 nm resulting from the first blue light B1. Each of the foregoing configurations can sufficiently reduce the amount of blue light that is emitted by the display device 101, and thus, the display device 101 can emit blue light that is friendly to user's eyes.

### Second Embodiment

FIG. 2 is a sectional view of a schematic configuration of a display device 102 according to a second embodiment of the present disclosure. The configuration of the display device 102 is the same as the configuration of the display device 101 with the exception of the following regard.

The display device 102 includes a red light-emitting portion 2R and a green light-emitting portion 2G. The red light-emitting portion 2R, the green light-emitting portion 2G, and the blue light-emitting portion 2B are provided on the substrate 1 and are individually provided in the cross-sectional view of the display device 102.

The red light-emitting portion 2R has a reflective electrode 3R, a red light-emitting layer 4R that emits red light R, and a transparent electrode 5R. The reflective electrode 3R, the red light-emitting layer 4R, and the transparent electrode 5R are stacked in the stated order on the substrate 1. The red light-emitting layer 4R emits the red light R in response to a current that flows between the reflective electrode 3R and transparent electrode 5R and is composed of, for instance, an OLED or a QLED. The red light R is defined as light whose peak wavelength ranges from 600 nm inclusive to 700 nm exclusive.

The green light-emitting portion 2G has a reflective electrode 3G, a green light-emitting layer 4G that emits green light G, and a transparent electrode 5G. The reflective electrode 3G, the green light-emitting layer 4G, and the transparent electrode 5G are stacked in the stated order on the substrate 1. The green light-emitting layer 4G emits the green light G in response to a current that flows between the reflective electrode 3G and transparent electrode 5G and is composed of, for instance, an OLED or a QLED. The green light G is defined as light whose peak wavelength ranges from 490 nm inclusive to 600 nm exclusive.

Each of the reflective electrodes 3R and 3G is a light-reflective electrode. Each of the transparent electrodes 5R and 5G is a light-transparent electrode. Each of the reflective electrodes 3R and 3G may be replaced with a light-transparent electrode, and at this time, the substrate 1 may be light-transparent as well.

A carrier functional layer may be formed as necessary between the reflective electrode 3R and red light-emitting layer 4R, and between the red light-emitting layer 4R and transparent electrode 5R. A carrier functional layer may be formed as necessary between the reflective electrode 3G and green light-emitting layer 4G, and between the green light-emitting layer 4G and transparent electrode 5G. Examples of the carrier functional layers include a hole injection layer, a hole transport layer, an electron injection layer, and an electron transport layer.

The red light-emitting layer 4R that emits the red light R, the green light-emitting 4G that emits the green light G, and the blue light-emitting layer 4B that emits the first blue light B1 are individually provided in the cross-sectional view of the display device 102. For instance, the red light-emitting layer 4R, the green light-emitting 4G, and the blue light-emitting layer 4B are color-coded separately from each other and are thus provided in the form of an island.

The display device 102 enables high-luminance and wide-color-gamut light emission.

### Third Embodiment

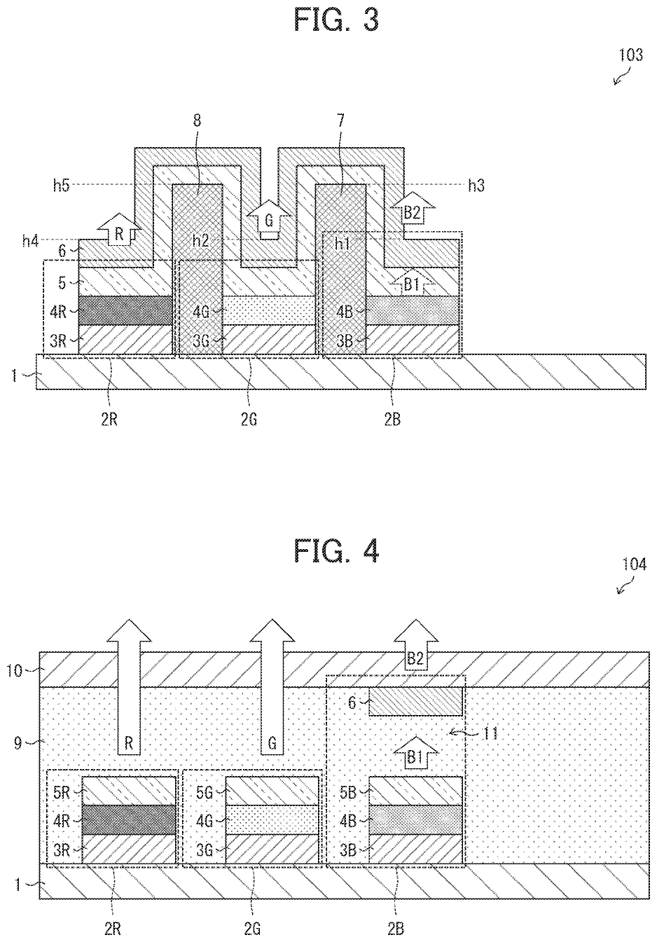

FIG. 3 is a sectional view of a schematic configuration of a display device 103 according to a third embodiment of the present disclosure. The configuration of the display device 103 is the same as the configuration of the display device 102 with the exception of the following regard.

The display device 103 includes a bank 7. The bank 7 is disposed between the blue light-emitting layer 4B and a particular light-emitting layer. The particular light-emitting layer is the red light-emitting layer 4R or the green light-emitting layer 4G. The particular light-emitting layer in FIG. 3 is the green light-emitting layer 4G.

The blue-wavelength conversion layer 6 is continuously provided over the blue light-emitting layer 4B, the bank 7, and the green light-emitting layer 4G. Each of a height h1 in the lowest part of the blue-wavelength conversion layer 6 over the blue light-emitting layer 4B, and a height h2 in the lowest part of the blue-wavelength conversion layer 6 over the green light-emitting layer 4G is lower than a height h3 at the peak of the bank 7. Each of the height h2, and a height h4 in the lowest part of the blue-wavelength conversion layer 6 over the red light-emitting layer 4R is lower than a height h5 at the peak of a bank 8.

It is noted that in the display device 103, the blue-wavelength conversion layer 6 over the blue light-emitting layer 4B has, along the bank 7, a portion as high as or higher than the height 3, because the blue-wavelength conversion layer 6 extends over the bank 7. Likewise, in the display device 103, the blue-wavelength conversion layer 6 over the green light-emitting layer 4G has, along the bank 7, a portion as high as or higher than the height 3, because of the foregoing structure. That is, each of a part of the height (e.g., height h1) of the blue-wavelength conversion layer 6 over the blue light-emitting layer 4B, and a part of the height (e.g., height h2) of the blue-wavelength conversion layer 6 over the green light-emitting layer 4G is lower than the height h3 at the peak of the bank 7.

However, if possible in configuration, the whole height of the blue-wavelength conversion layer 6 over the blue light-emitting layer 4B is preferably lower than the height h3 at the peak of the bank 7. Likewise, if possible in configuration, the whole height of the blue-wavelength conversion layer 6 over the green light-emitting layer 4G is preferably lower than the height h3 at the peak of the bank 7. Such a configuration is feasible by forming the side surface of a bank corresponding to the bank 7 into a gently sloped surface.

The foregoing configuration can increase the size of the blue-wavelength conversion layer 6. Consequently, the display device 103 that is mechanically stable can be achieved, enabling improvement in the yield of the display device 103, and enabling the display device 103 to have a long life.

In addition, the foregoing configuration, in which the height h3 is larger than both of the heights h1 and h2, can prevent mutual interference between the second blue light B2 emitted from the blue-wavelength conversion layer 6 over the blue light-emitting layer 4B, and the green light G emitted from the green light-emitting layer 4G. In addition, the foregoing configuration, in which the height h5 is larger than both of the heights h2 and h4, can prevent mutual interference between the green light G emitted from the green light-emitting layer 4G, and the red light R emitted from the red light-emitting layer 4R.

The display device 103 includes the bank 8 in addition to the bank 7. The bank 8 is disposed between the red light-emitting layer 4R and the green light-emitting layer 4G. The banks 7 and 8 may be integrated together. The blue-wavelength conversion layer 6 is continuously provided over the bank 8 and the red light-emitting layer 4R, in addition to over the blue light-emitting layer 4B, the bank 7, and the green light-emitting layer 4G.

The display device 103 includes a transparent electrode 5 instead of the transparent electrodes 5R, 5G, and 5B. The transparent electrode 5 is continuously provided over the red light-emitting layer 4R, the green light-emitting layer 4G, and the blue light-emitting layer 4B. The transparent electrode 5 serves as the function of the transparent electrode 5R, the function of the transparent electrode 5G, and the function of the transparent electrode 5B. The blue-wavelength conversion layer 6 is provided over the transparent electrode 5.

### Fourth Embodiment

FIG. 4 is a sectional view of a schematic configuration of a display device 104 according to a fourth embodiment of the present disclosure. The configuration of the display device 104 is the same as the configuration of the display device 102 with the exception of the following regard.

The display device 104 further includes a sealant 9 and a protective film 10. The sealant 9 is provided on the substrate 1. The sealant 9 seals the red light-emitting portion 2R, the green light-emitting portion 2G, and the blue light-emitting portion 2B. The blue light-emitting portion 2B has a space 11 formed between (1) the reflective electrode 3B, blue light-emitting layer 4B, and transparent electrode 5B, and (2) the blue-wavelength conversion layer 6, and the sealant 9 is filled in the space 11.

The protective film 10 is a light-transparent film attached to the surface of the sealant 9 (in FIG. 4, furthermore to the surface of the blue-wavelength conversion layer 6). As the result of the attachment of the protective film 10, one display surface of the display device 104 (in FIG. 4, the upper end surface of the display device 104) is flat.

The display device 104 has a flat upper end surface and a flat lower end surface, and the display device 104 is thin. The display device 104 is hence suitable when it is used as a film-shaped display device.

The aforementioned configuration of the display device 104 different from that of the display device 102 may be combined with the configuration of the display device 101, or the configuration of the display device 103.

Additional Note Each of the display devices 101 to 104 may further include a light-scattering layer that scatters the second blue light B2 emitted from the blue-wavelength conversion layer 6. Further, the blue-wavelength conversion layer 6 may contain a light-scattering material, or resin.

### SUMMARY

A display device according to a first aspect of the present disclosure includes the following: a blue light-emitting layer composed of an organic light-emitting diode or a quantum-dot light-emitting diode; and a blue-wavelength conversion layer, wherein the blue light-emitting layer is configured to emit first blue light having a peak wavelength of 455 nm or less, the blue-wavelength conversion layer is provided over at least the blue light-emitting layer and is configured to convert the first blue light into second blue light having a peak wavelength that is longer than the peak wavelength of the first blue light and is 490 nm or less, and Sb1<Eb×Sb2 is satisfied, where Eb is the energy conversion efficiency of the blue-wavelength conversion layer, where Sb1 is the standard photopic luminous efficiency of the first blue light, where Sb2 is the standard photopic luminous efficiency of the second blue light.

The display device according to a second aspect of the present disclosure is configured, in the first aspect, such that the blue-wavelength conversion layer is cadmium-free.

The display device according to a third aspect of the present disclosure is configured, in the first or second aspect, such that the blue-wavelength conversion layer contains a first quantum dot material, and the first quantum dot material has a core made of any of InP, ZnSe, ZnSeTe, and ZnTe.

The display device according to a fourth aspect of the present disclosure is configured, in any one of the first to third aspects, such that the blue light-emitting layer is cadmium-free.

The display device according to a fifth aspect of the present disclosure is configured, in any one of the first to fourth aspects, such that the blue light-emitting layer contains a second quantum dot material, and the second quantum dot material has a core made of any of ZnSe, ZnSeTe, and ZnTe.

The display device according to a sixth aspect of the present disclosure is configured, in any one of the first to fifth aspects, such that the peak wavelength of the second blue light is longer than 455 nm, and in the spectrum of light that is emitted by a blue light-emitting portion having the blue light-emitting layer and the blue-wavelength conversion layer, the spectral radiance of light at a peak that is longer than wavelength 455 nm resulting from the second blue light is larger than the spectral radiance of light at a peak that is equal to or less than wavelength 455 nm resulting from the first blue light.

The display device according to a seventh aspect of the present disclosure is configured, in any one of the first to fifth aspects, such that the spectrum of light that is emitted by a blue light-emitting portion having the blue light-emitting layer and the blue-wavelength conversion layer does not include a peak that is equal to or less than wavelength 455 nm resulting from the first blue light.

The display device according to an eighth aspect of the present disclosure is configured, in any one of the first to seventh aspects, such that a red light-emitting layer configured to emit red light, a green light-emitting layer configured to emit green light, and the blue light-emitting layer are individually provided in the cross-sectional view of the display device.

The display device according to a ninth aspect of the present disclosure in the eighth aspect includes a bank disposed between the blue light-emitting layer and a particular light-emitting layer that is the red light-emitting layer or the green light-emitting layer, wherein the blue-wavelength conversion layer is continuously provided over the blue light-emitting layer, the bank, and the particular light-emitting layer, and each of at least a part of the height of the blue-wavelength conversion layer over the blue light-emitting layer, and at least a part of the height of the blue-wavelength conversion layer over the particular light-emitting layer is lower than the height at the peak of the bank.

The present disclosure is not limited to the foregoing embodiments. Various modifications can be made within the scope of the claims. An embodiment that is obtained in combination as appropriate with the technical means disclosed in the respective embodiments is also included in the technical scope of the present disclosure. Furthermore, combining the technical means disclosed in the respective embodiments can form a new technical feature.

1. A display device comprising:
a blue light-emitting layer composed of an organic light-emitting diode or a quantum-dot light-emitting diode; and
a blue-wavelength conversion layer,
wherein the blue light-emitting layer is configured to emit first blue light having a peak wavelength of 455 nm or less,
the blue-wavelength conversion layer is provided over at least the blue light-emitting layer and is configured to convert the first blue light into second blue light having a peak wavelength that is longer than the peak wavelength of the first blue light and is 490 nm or less, and
Sb1<Eb×Sb2 is satisfied, where Eb is energy conversion efficiency of the blue-wavelength conversion layer, where Sb1 is standard photopic luminous efficiency of the first blue light, where Sb2 is standard photopic luminous efficiency of the second blue light.

2. The display device according to claim 1, wherein the blue-wavelength conversion layer is cadmium-free.

3. The display device according to claim 1, wherein
the blue-wavelength conversion layer contains a first quantum dot material, and
the first quantum dot material has a core made of any of InP, ZnSe, ZnSeTe, and ZnTe.

4. The display device according to claim 1, wherein the blue light-emitting layer is cadmium-free.

5. The display device according to claim 1, wherein
the blue light-emitting layer contains a second quantum dot material, and
the second quantum dot material has a core made of any of ZnSe, ZnSeTe, and ZnTe.

6. The display device according to claim 1, wherein
a peak wavelength of the second blue light is longer than 455 nm, and
in a spectrum of light that is emitted by a blue light-emitting portion having the blue light-emitting layer and the blue-wavelength conversion layer, spectral radiance of light at a peak that is longer than wavelength 455 nm resulting from the second blue light is larger than spectral radiance of light at a peak that is equal to or less than wavelength 455 nm resulting from the first blue light.

7. The display device according to claim 1, wherein a spectrum of light that is emitted by a blue light-emitting portion having the blue light-emitting layer and the blue-wavelength conversion layer does not include a peak that is equal to or less than wavelength 455 nm resulting from the first blue light.

8. The display device according to claim 1, wherein a red light-emitting layer configured to emit red light, a green light-emitting layer configured to emit green light, and the blue light-emitting layer are individually provided in a cross-sectional view of the display device.

9. The display device according to claim 8, comprising
a bank disposed between the blue light-emitting layer and a particular light-emitting layer that is the red light-emitting layer or the green light-emitting layer,
wherein the blue-wavelength conversion layer is continuously provided over the blue light-emitting layer, the bank, and the particular light-emitting layer, and
each of at least a part of a height of the blue-wavelength conversion layer over the blue light-emitting layer, and at least a part of a height of the blue-wavelength conversion layer over the particular light-emitting layer is lower than a height at a peak of the bank.
